(19) United States
(12) Patent Application Publication
(10) Pub. No.: US 2022/0375838 A1
(43) Pub. Date: Nov. 24, 2022

(54) PACKAGE COMPRISING INTEGRATED DEVICES COUPLED THROUGH A BRIDGE

(71) Applicant: QUALCOMM Incorporated, San Diego, CA (US)

(72) Inventors: Hong Bok WE, San Diego, CA (US); Aniket PATIL, San Diego, CA (US); Zhijie WANG, San Diego, CA (US); Marcus HSU, San Diego, CA (US)

(21) Appl. No.: 17/328,666

(22) Filed: May 24, 2021

(51) Int. Cl. H01L 23/498; H01L 23/538; H01L 23/00; H01L 23/535; H01L 23/28

(52) U.S. Cl. CPC H01L 23/49811; H01L 23/5386; H01L 24/04; H01L 23/535; H01L 23/28; H01L 2224/02

(57) ABSTRACT

A package comprising a first integrated device comprising a first plurality of under bump metallization interconnects; a second integrated device comprising a second plurality of under bump metallization interconnects; a bridge coupled to the first integrated device and the second integrated device; an encapsulation layer at least partially encapsulating the first integrated device, the second integrated device, and the bridge; a metallization portion located over the first integrated device, the second integrated device, the bridge and the encapsulation layer, where the metallization portion includes at least one dielectric layer and a plurality of metallization interconnects; a first plurality of pillar interconnects coupled to the first plurality of under bump metallization interconnects, the first plurality of interconnects located in the encapsulation layer; and a second plurality of pillar interconnects coupled to the second plurality of under bump metallization interconnects, the second plurality of pillar interconnects located in the encapsulation layer.

### FIELD

Various features relate to package comprising integrated devices.

### BACKGROUND

A package may include a substrate and several integrated devices that are mounted on the substrate. The integrated devices may be configured to communicate with each other through the substrate. There is an ongoing need to provide package having integrated devices with improved communication performances between integrated devices. These packages may have smaller footprints and lower profiles.

### SUMMARY

Various features relate to package comprising integrated devices.

One example provides a package that includes a first integrated device comprising a first plurality of under bump metallization interconnects; a second integrated device comprising a second plurality of under bump metallization interconnects; a bridge coupled to the first integrated device and the second integrated device; an encapsulation layer at least partially encapsulating the first integrated device, the second integrated device, and the bridge; a metallization portion located over the first integrated device, the second integrated device, the bridge and the encapsulation layer, where the metallization portion includes at least one dielectric layer and a plurality of metallization interconnects; a first plurality of pillar interconnects coupled to the first plurality of under bump metallization interconnects and the metallization portion, the first plurality of pillar interconnects located in the encapsulation layer; and a second plurality of pillar interconnects coupled to the second plurality of under bump metallization interconnects and the metallization portion, the second plurality of pillar interconnects located in the encapsulation layer.

Another example provides an apparatus that includes a first integrated device comprising a first plurality of under bump metallization interconnects; a second integrated device comprising a second plurality of under bump metallization interconnects; means for bridge interconnection coupled to the first integrated device and the second integrated device; means for encapsulation at least partially encapsulating the first integrated device, the second integrated device, and the means for bridge interconnection; a metallization portion located over the first integrated device, the second integrated device, the means for bridge interconnection and the means for encapsulation, wherein the metallization portion includes at least one dielectric layer and a plurality of metallization interconnects; a first plurality of pillar interconnects coupled to the first plurality of under bump metallization interconnects and the metallization portion, the first plurality of pillar interconnects located in the means for encapsulation; and a second plurality of pillar interconnects coupled to the second plurality of under bump metallization interconnects and the metallization portion, the second plurality of pillar interconnects located in the means for encapsulation.

Another example provides a method for fabricating a package. The method couples a bridge to a first integrated device and a second integrated device. The first integrated device comprises a first plurality of under bump metallization interconnects. The second integrated device comprises a second plurality of under bump metallization interconnects. The method forms a first plurality of pillar interconnects over the first plurality of under bump metallization interconnects. The method forms a second plurality of pillar interconnects over the second plurality of under bump metallization interconnects. The method forms an encapsulation layer that at least partially encapsulates the first integrated device, the second integrated device, the bridge, the first plurality of pillar interconnects and the second plurality of pillar interconnects. The method forms a metallization portion over the first integrated device, the second integrated device, the bridge and the encapsulation layer, wherein forming the metallization portion includes forming at least one dielectric layer and forming a plurality of metallization interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a package that includes integrated devices coupled through a bridge.

FIG. 2 illustrates a package that includes integrated devices coupled through a bridge.

FIG. 3 illustrates a package on package (PoP) with a package that includes integrated devices coupled through a bridge.

FIG. 4 illustrates a package that includes integrated devices coupled through a plurality of bridges.

FIGS. 5A-5D illustrate an exemplary sequence for fabricating a package that includes integrated devices coupled through a bridge.

FIG. 6 illustrates an exemplary flow diagram of a method for fabricating a package that includes integrated devices coupled through a bridge.

FIGS. 7A-7C illustrate an exemplary sequence for fabricating a package that includes integrated devices coupled through a bridge.

FIG. 8 illustrates an exemplary flow diagram of a method for fabricating a package that includes integrated devices coupled through a bridge.

FIG. 9 illustrates various electronic devices that may integrate a die, an integrated device, an integrated passive device (IPD), a device package, a package, an integrated circuit and/or PCB described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a first integrated device comprising a first plurality of under bump metallization interconnects; a second integrated device comprising a second plurality of under bump metallization interconnects; a bridge coupled to the first integrated device and the second integrated device; an encapsulation layer at least partially encapsulating the first integrated device, the second integrated device, and the bridge; a metallization portion located over the first integrated device, the second integrated device, the bridge and the encapsulation layer, where the metallization portion includes at least one dielectric layer and a plurality of metallization interconnects; a first plurality of pillar interconnects coupled to the first plurality of under bump metallization interconnects and the metallization portion, the first plurality of pillar interconnects located in the encapsulation layer; and a second plurality of pillar interconnects coupled to the second plurality of under bump metallization interconnects and the metallization portion, the second plurality of pillar interconnects located in the encapsulation layer. The use of the bridge may help provide shorter electrical path between the integrated devices, which can help improve the performance of the integrated devices and the package.

### Exemplary Package Comprising Integrated Devices Coupled Through a Bridge

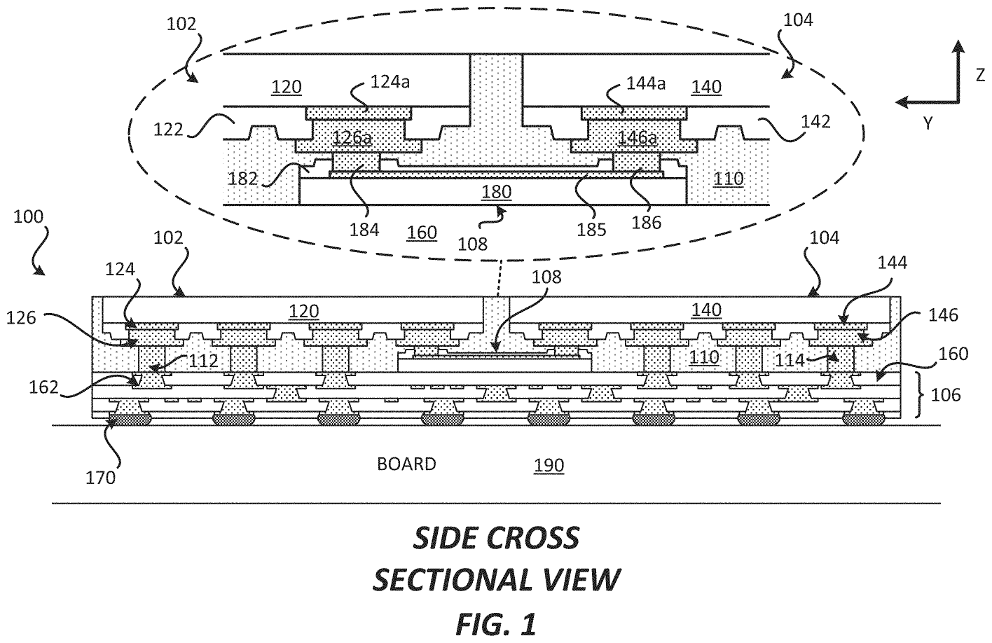

FIG. 1 illustrates an example of a package 100 that includes integrated devices that are coupled through a bridge. The package 100 is coupled to a board 190 (e.g., printed circuit board) through a plurality of solder interconnects 170. The package 100 includes an integrated device 102, an integrated device 104, a metallization portion 106, a bridge 108, and an encapsulation layer 110.

The metallization portion 106 includes at least one dielectric layer 160 and a plurality of metallization interconnects 162. A back side of the bridge 108 faces the metallization portion 106. The back side of the bridge 108 may be coupled to the metallization portion 106. The metallization portion 106 is coupled to the encapsulation layer 110. The encapsulation layer 110 may at least partially encapsulate the bridge 108. The encapsulation layer 110 may be a means for encapsulation. The integrated device 102 and the integrated device 104 may be coupled to the bridge 108. A front side of the integrated device 102 may face a front side of the bridge 108. The front side of the integrated device 102 may also face the metallization portion 106. The metallization portion 106 may be a first metallization portion. The integrated device 102 may be coupled (e.g., mechanically coupled, electrically coupled) to the metallization portion 106 through a plurality of pillar interconnects 112. The plurality of pillar interconnects 112 may be a plurality of through mold vias (e.g., TMVs) and/or a plurality of through mold interconnects.

Similarly, a front side of the integrated device 104 may face a front side of the bridge 108. The front side of the integrated device 104 may also face the metallization portion 106. The integrated device 104 may be coupled (e.g., mechanically coupled, electrically coupled) to the metallization portion 106 through a plurality of pillar interconnects 114. The plurality of pillar interconnects 114 may be a plurality of through mold vias (e.g., TMVs) and/or a plurality of through mold interconnects. The integrated device 102 and the integrated device 104 may be part of a back side of the package 100.

The metallization portion 106 may at least partially encapsulate the bridge 108, the plurality of pillar interconnects 112, the plurality of pillar interconnects 114, the integrated device 102 and/or the integrated device 104. The metallization portion 106 may part and/or be located in a front side of the package 100.

The integrated device 102 may be configured to be electrically coupled to the integrated device 104 through the bridge 108. One advantage of the bridge 108 is that the bridge 108 provides shorter electrical paths for electrical currents (e.g., electrical signals, input/output signals) between the integrated device 102 and the integrated device 104, which helps improve the overall performance of the package 100 and the performances of the integrated device 102 and the integrated device 104. Electrical currents between the integrated device 102 and the integrated device 104 that travel through the bridge 108 do not need to travel through the plurality of pillar interconnects 112, the plurality of pillar interconnects 114 and the metallization portion 106. Moreover, as will be further described below, the bridge 108 may be configured to include a plurality of bridge interconnects that include a width of 1 micrometer or less (e.g., 0.5-1 micrometer). The bridge interconnects of the bridge 108 may have widths that are smaller than the widths of the plurality of metallization interconnects 162 of the metallization portion 106. The smaller width of the bridge interconnects may help provide more electrical paths in a given region between the integrated device 102 and the integrated device 104, which can help enable faster communication and more communication paths between the integrated device 102 and the integrated device 104.

The integrated device 102 (e.g., first integrated device) may include a die (e.g., bare semiconductor die). The integrated device 102 includes a die substrate 120, a passivation layer 122, and a plurality of pads 124. The integrated device 102 may include a plurality of under bump metallization interconnects 126. The die substrate 120 may include silicon. The die substrate 120 may include a plurality of active devices (e.g., transistors). A front end of line (FEOL) process may be used to fabricate the die substrate 120. The plurality of pads 124 may be located over the die substrate 120. The plurality of pads 124 may be a top layer of the integrated device 102. The plurality of pads 124 may be configured to be electrically coupled to the active devices (e.g., transistors). The passivation layer 122 may be located over the plurality of pads 124 and the die substrate 120. The integrated device 102 may include a frontside and backside. The frontside the integrated device 102 may include the side of the integrated device 102 that includes the plurality of under bump metallization interconnects 126, the plurality of pads 124 and/or the passivation layer 122. The backside of the integrated device 102 may include the side that faces away from the plurality of pads 124. The backside of the integrated device 102 may include the side that includes the die substrate 120. The plurality of under bump metallization interconnects 126 is coupled to the plurality of pads 124.

The integrated device 104 (e.g., second integrated device) may include a die (e.g., bare semiconductor die). The integrated device 104 includes a die substrate 140, a passivation layer 142, and a plurality of pads 144. The integrated device 104 may include a plurality of under bump metallization interconnects 146. The die substrate 140 may include silicon. The die substrate 140 may include a plurality of active devices (e.g., transistors). A front end of line (FEOL) process may be used to fabricate the die substrate 140. The plurality of pads 144 may be located over the die substrate 140. The plurality of pads 144 may be a top layer of the integrated device 104. The plurality of pads 144 may be configured to be electrically coupled to the active devices (e.g., transistors). The passivation layer 142 may be located over the plurality of pads 144 and the die substrate 140. The integrated device 104 may include a frontside and backside. The frontside the integrated device 104 may include the side of the integrated device 104 that includes the plurality of under bump metallization interconnects 146, the plurality of pads 144 and/or the passivation layer 142. The backside of the integrated device 104 may include the side that faces away from the plurality of pads 144. The backside of the integrated device 104 may include the side that includes the die substrate 140. The plurality of under bump metallization interconnects 146 is coupled to the plurality of pads 144.

In some implementations, the integrated device 102 and/or the integrated device 104 may include one or more interconnects and one or more dielectric layers located over the die substrate (e.g., 120, 140). The one or more interconnects and one or more dielectric layers may be located between the die substrate (e.g., 120, 140) and the passivation layer (e.g., 122, 142). In such instances, the plurality of pads (e.g., 124, 144) may be coupled to the one or more interconnects. The one or more interconnects may be coupled to one or more active devices (e.g., transistors). A back end of line (BEOL) process may be used to fabricate the one or more interconnects and one or more dielectric layers.

The bridge 108 includes a substrate 180 (e.g., die substrate), a passivation layer 182. a plurality of bridge interconnects 185, a plurality of bridge interconnects 184, and a plurality of bridge interconnects 186. The bridge 108 may be a means for bridge interconnection. The bridge 108 may be a bridge die. The bridge 108 may be a passive die. The substrate 180 may include silicon. The plurality of bridge interconnects 185 is formed and located over the substrate 180. The passivation layer 182 may be located over the plurality of bridge interconnects 185. The plurality of bridge interconnects 184 is coupled to the plurality of bridge interconnects 185. The plurality of bridge interconnects 186 is coupled to the plurality of bridge interconnects 185. The plurality of bridge interconnects 184 and/or the plurality of bridge interconnects 186 may include a plurality of bridge under bump metallization interconnects and/or a plurality of bridge post interconnects. The plurality of bridge interconnects 185 may be arranged in rows of bridge interconnects. In some implementations, one or more bridge interconnects from the plurality of bridge interconnects 185 may have a width of 1 micrometer or less (e.g., 0.5-1 micrometer). In some implementations, one or more bridge interconnect from the plurality of bridge interconnects 185 may have a minimum width of 0.5 micrometer. In some implementations, a spacing between two adjacent bridge interconnects from the plurality of bridge interconnects 185 may be 1 micrometer or less (e.g., 0.5-1 micrometer). In some implementations, a minimum spacing between two adjacent bridge interconnects from the plurality of bridge interconnects 185 may be 0.5 micrometer.

The bridge 108 is coupled to the integrated device 102 such that the plurality of under bump metallization interconnects 126 is coupled to the plurality of bridge interconnects 184. There may or may not be an interface between the plurality of under bump metallization interconnects 126 and the plurality of bridge interconnects 184. The bridge 108 is coupled to the integrated device 104 such that the plurality of under bump metallization interconnects 146 is coupled to the plurality of bridge interconnects 186. There may or may not be an interface between the plurality of under bump metallization interconnects 146 and the plurality of bridge interconnects 186.

An electrical path between the integrated device 102 and the integrated device 104 may include a pad 124a, an under bump metallization interconnect 126a, a bridge interconnect from the plurality of bridge interconnects 184, a bridge interconnect from the plurality of bridge interconnects 185, a bridge interconnect from the plurality of bridge interconnects 186, an under bump metallization interconnect 146a, and a pad 144a. The bridge 108 may include several electrical paths that may be arranged in rows of bridge interconnects. The electrical path may be configured to allow electrical currents (e.g., input/output signals) between the integrated device 102 and the integrated device 104.

FIG. 1 illustrates an interface between the under bump metallization interconnect 126a and the bridge interconnect from the plurality of bridge interconnects 184. However, in some implementations, there may not be an interface between the under bump metallization interconnect 126a and the bridge interconnect from the plurality of bridge interconnects 184. In some implementations, a front side of the under bump metallization interconnect 126a is coupled to the bridge interconnect from the plurality of bridge interconnects 184. The front side of an under bump metallization interconnect may be the side that is the widest part of the under bump metallization interconnect. A metal-to-metal oxide bonding process and/or a hybrid bonding process may be used to couple the front side of the under bump metallization interconnect 126a to the bridge interconnect from the plurality of bridge interconnects 184.

FIG. 1 also illustrates an interface between the under bump metallization interconnect 146a and the bridge interconnect from the plurality of bridge interconnects 186. However, in some implementations, there may not be an interface between the under bump metallization interconnect 146a and the bridge interconnect from the plurality of bridge interconnects 186. In some implementations, a front side of the under bump metallization interconnect 146a is coupled to the bridge interconnect from the plurality of bridge interconnects 186. A metal-to-metal oxide bonding process and/or a hybrid bonding process may be used to couple the front side of the under bump metallization interconnect 146a to the bridge interconnect from the plurality of bridge interconnects 186.

Different components of the package 100 may have different sizes and/or shapes. For example, the integrated device(s) (e.g., 102, 104) may have a thickness of about 140 micrometers. The passivation layer (e.g., 122, 142) may have a thickness of about 5 micrometers. The plurality of under bump metallization interconnects (e.g., 126, 146) may have a width of about 50 micrometers. The bridge 108 may have a thickness of about 25 micrometers. The plurality of bridge interconnects (e.g., 184, 186) may have a width of about 30 micrometers. Each of the metal layers of the plurality of metallization interconnects 162 may have a thickness of about 4-5 micrometers. Different implementations may couple the bridge 108 to the integrated device 102 and the integrated device 104 differently.

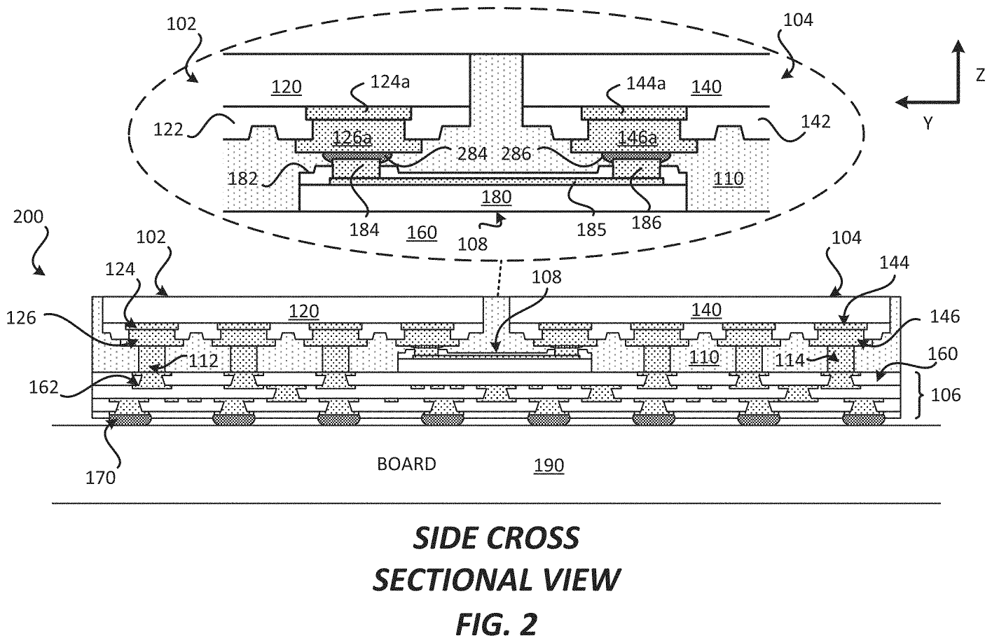

FIG. 2 illustrates an example of a package 200 that includes integrated devices that are coupled through a bridge. The package 200 is coupled to a board 190 (e.g., printed circuit board) through the plurality of solder interconnects 170. The package 200 is similar to the package 100, and thus include similar components as the package 100. The package 200 includes the integrated device 102, the integrated device 104, the metallization portion 106, the bridge 108, and the encapsulation layer 110.

FIG. 2 illustrates the that bridge 108 is coupled to the integrated device 102 through a plurality of solder interconnects 284. FIG. 2 also illustrates that the bridge 108 is coupled to the integrated device 104 through the plurality of solder interconnects 286. The plurality of solder interconnects 284 is coupled to at least one under bump metallization interconnect (e.g., 126a) from the plurality of under bump metallization interconnects 126, and the plurality of bridge interconnects 184. The plurality of solder interconnects 286 is coupled to at least one under bump metallization interconnect (e.g., 146a) from the plurality of under bump metallization interconnects 146, and the plurality of bridge interconnects 186.

An electrical path between the integrated device 102 and the integrated device 104 may include a pad 124a, an under bump metallization interconnect 126a, a solder interconnect from the plurality of solder interconnects 284, a bridge interconnect from the plurality of bridge interconnects 184, a bridge interconnect from the plurality of bridge interconnects 185, a bridge interconnect from the plurality of bridge interconnects 186, a solder interconnect from the plurality of solder interconnect 286, an under bump metallization interconnect 146a, and a pad 144a. The bridge 108 may include several electrical paths that may be arranged in rows of bridge interconnects. The electrical path may be configured to allow electrical currents (e.g., input/output signals) between the integrated device 102 and the integrated device 104.

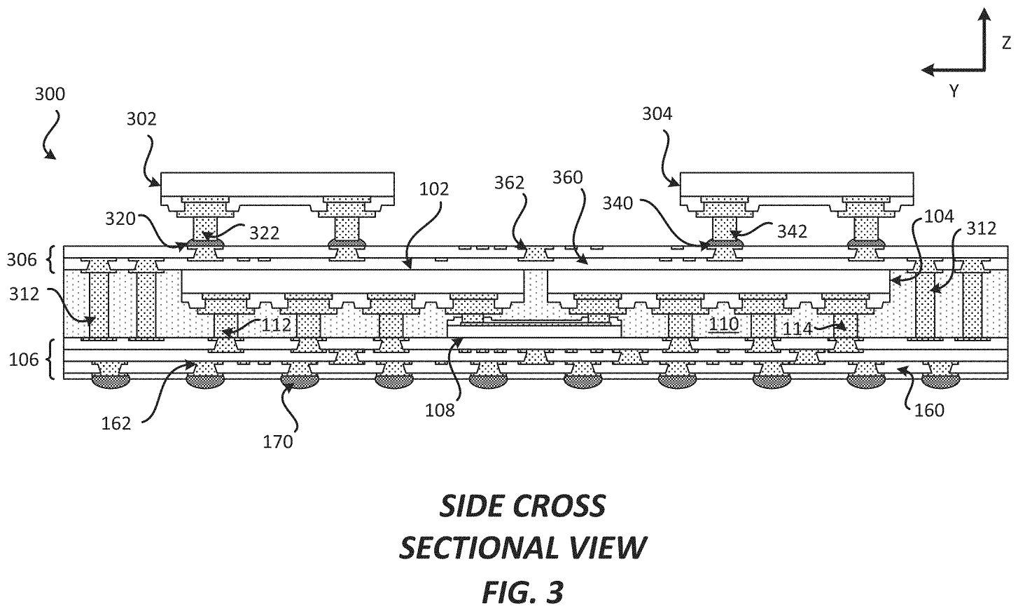

In some implementations, the packages of FIGS. 1 and 2 may be implemented as part of a package on package (PoP). FIG. 3 illustrates a package 300 that includes integrated devices that are coupled through a bridge. The package 300 is coupled to the board 190 (e.g., printed circuit board) through the plurality of solder interconnects 170. The package 300 is similar to the package 100, and thus may include similar components as the package 100. The package 300 may also include additional components. The package 300 includes the integrated device 102, the integrated device 104, the metallization portion 106, the bridge 108, the encapsulation layer 110 and a metallization portion 306. An integrated device 302 and an integrated device 304 are coupled to the package 300. The package 300, the integrated device 302 and the integrated device 304 may be implemented as a package on package (PoP). In some implementations, the metallization portion 106 may be a first metallization portion 106 and the metallization portion 306 may be a second metallization portion.

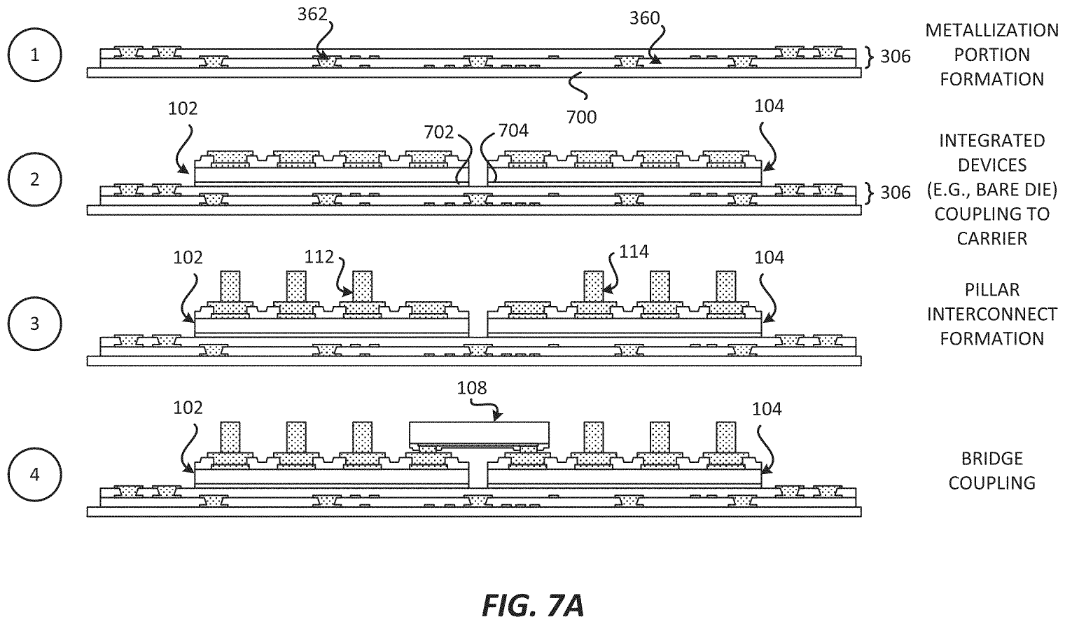

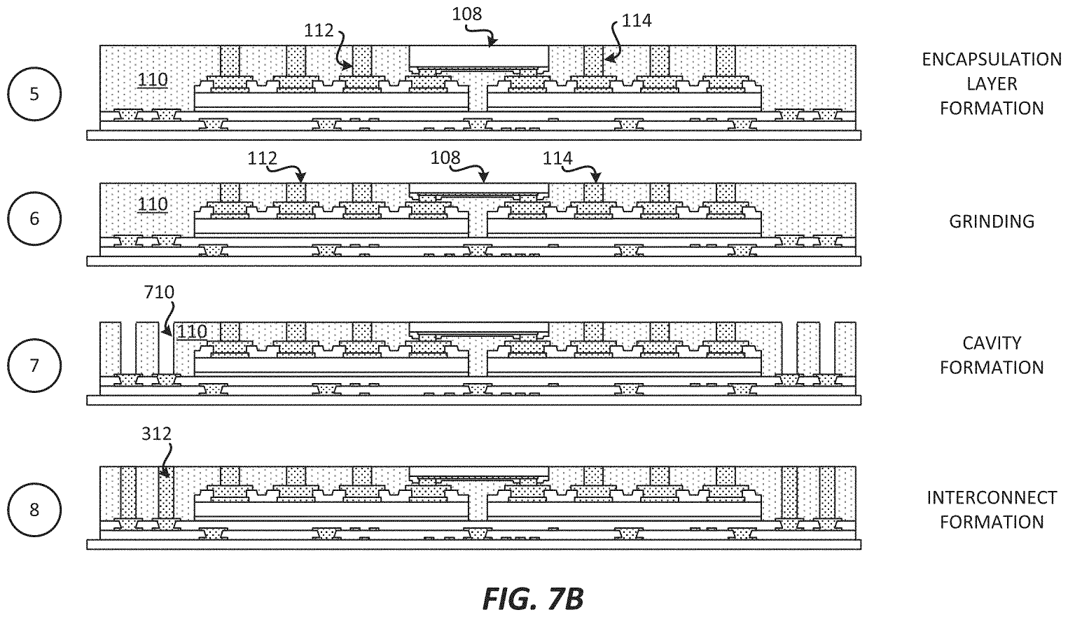

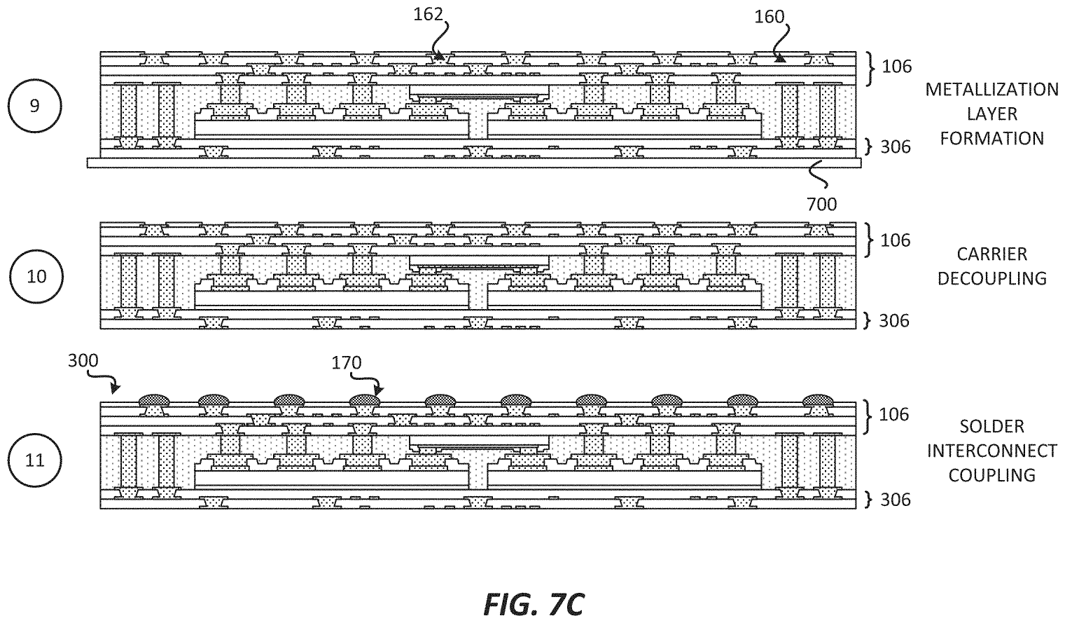

The integrated device 102, the integrated device 104, the metallization portion 106, the bridge 108 and the encapsulation layer 110 may be coupled to each other in a similar manner as described for the package 100. The integrated device 102 may be configured to be coupled to the integrated device 104 through the bridge 108, in a similar manner as described for the package 100 of FIG. 1 and/or the package 200 of FIG. 2. The metallization portion 306 may be coupled to the encapsulation layer 110, the back side of the integrated device 102 and the back side of the integrated device 104. In some implementations, one or more adhesive (not shown) may be used to couple the back side of the integrated device 102 and/or the back side of the integrated device 104 to the metallization portion 306. The use of an adhesive is described below in at least FIGS. 7A-7C. The metallization portion 306 may be considered part of a back side of the package 300. The metallization portion 306 includes at least one dielectric layer 360 (e.g., at least one second dielectric layer) and a plurality of interconnects 362. The plurality of interconnects 362 may include a plurality of metallization interconnects (e.g., second plurality of metallization interconnects). The metallization portion 306 may be configured to be electrically coupled to the metallization portion 106 through a plurality of pillar interconnects 312. The plurality of pillar interconnects 312 may be coupled to the plurality of metallization interconnects 162 and the plurality of interconnects 362. The plurality of pillar interconnects 312 may be located in the encapsulation layer 110. The plurality of pillar interconnects 312 may be a plurality of through mold vias (e.g., TMVs) and/or a plurality of through mold interconnects. The encapsulation layer 110 may include a mold, a resin, an epoxy and/or polymer. The encapsulation layer 110 may be a means for encapsulation.

The integrated device 302 is coupled to the metallization portion 306 through the plurality of pillar interconnects 322 and/or the plurality of solder interconnects 320. For example, the integrated device 302 is coupled to the plurality of interconnects 362 through the plurality of pillar interconnects 322 and/or the plurality of solder interconnects 320. The integrated device 304 is coupled to the metallization portion 306 through the plurality of pillar interconnects 342 and/or the plurality of solder interconnects 340. For example, the integrated device 304 is coupled to the plurality of interconnects 362 through the plurality of pillar interconnects 342 and/or the plurality of solder interconnects 340. The integrated device 302 and/or the integrated device 304 may be similar to the integrated device 102 and/or the integrated device 104.

In some implementations, the integrated device 302 may be configured to be electrically coupled to the integrated device 102 through the plurality of pillar interconnects 322, the plurality of solder interconnects 320, the plurality of interconnects 362 of the metallization portion 306, the plurality of pillar interconnects 312, the plurality of metallization interconnects 162 of the metallization portion 106 and the plurality of pillar interconnects 112.

In some implementations, the integrated device 304 may be configured to be electrically coupled to the integrated device 104 through the plurality of pillar interconnects 342, the plurality of solder interconnects 340, the plurality of interconnects 362 of the metallization portion 306, the plurality of pillar interconnects 312, the plurality of metallization interconnects 162 of the metallization portion 106 and the plurality of pillar interconnects 114.

The plurality of metallization interconnects 162 may be a means for metallization interconnection. The plurality of metallization interconnects 362 may be a means for metallization interconnection. The plurality of metallization interconnects 162 and/or 362 may include at least one redistribution layer (RDL) interconnects (e.g., redistribution interconnects). A redistribution layer interconnect may include a U-shape or V-shape. The terms “U-shape” and” V-shape” shall be interchangeable. The terms “U-shape” and “V-shape” may refer to the side profile shape of the interconnects and/or redistribution layer interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

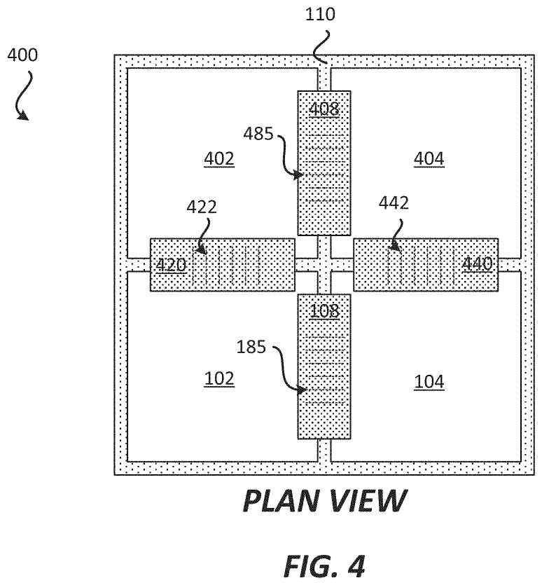

It is noted that a package may include more than two integrated devices and more than one bridge. FIG. 4 illustrates a plan view of a package 400 that includes several integrated devices coupled through a bridge. The package 400 includes the integrated device 102, the integrated device 104, an integrated device 402, an integrated device 404, the bridge 108, a bridge 408, a bridge 420 and a bridge 440. In some implementations, the packages 100, 200 and/or 300 may be represented by the package 400.

As shown in FIG. 4, the integrated device 102 is coupled to the integrated device 104 through the bridge 108. The integrated device 102 may communicate with the integrated device 104 through the bridge 108. The integrated device 102 is coupled to the integrated device 402 through the bridge 420. The integrated device 102 may communicate with the integrated device 402 through the bridge 420. The integrated device 402 is coupled to the integrated device 404 through the bridge 408. The integrated device 402 may communicate with the integrated device 404 through the bridge 408. The integrated device 404 is coupled to the integrated device 104 through the bridge 440. The integrated device 404 may communicate with the integrated device 104 through the bridge 440. The bridge 408 includes a plurality of bridge interconnects 485. The bridge 420 includes a plurality of bridge interconnects 422. The bridge 440 includes a plurality of bridge interconnects 442. The bridge 408, the bridge 420 and/or the bridge 440 may be similar to the bridge 108. However, the bridge 408, the bridge 420 and/or the bridge 440 may have different sizes, shapes, and/or different numbers of bridge interconnects.

An integrated device (e.g., 102, 104, 302, 304, 402, 404) may include a die (e.g., bare die). Any of the integrated devices described in the disclosure may have a structure similar to what is described for the integrated devices 102 and/or 104. The integrated device may include a radio frequency (RF) device, an analog device, a passive device, a filter, a capacitor, an inductor, an antenna, a transmitter, a receiver, a surface acoustic wave (SAW) filters, a bulk acoustic wave (BAW) filter, a light emitting diode (LED) integrated device, a silicon (Si) based integrated device, a silicon carbide (SiC) based integrated device, a GaAs based integrated device, a GaN based integrated device, a memory, power management processor, and/or combinations thereof.

Having described various packages, a sequence and process for fabricating a package will be described below.

### Exemplary Sequence for Fabricating a Package Comprising Integrated Devices Coupled Through a Bridge

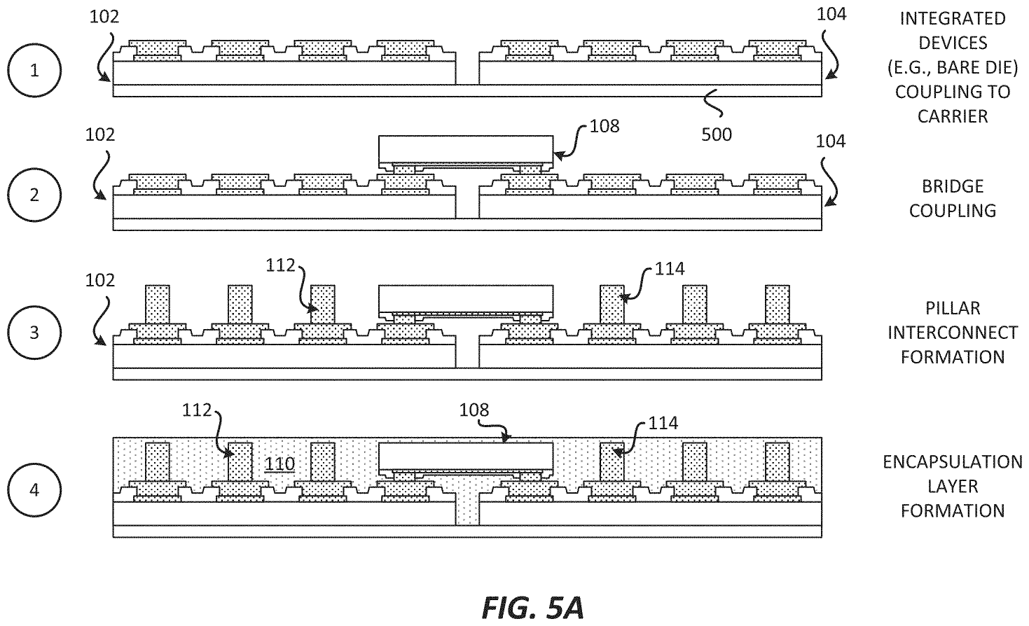

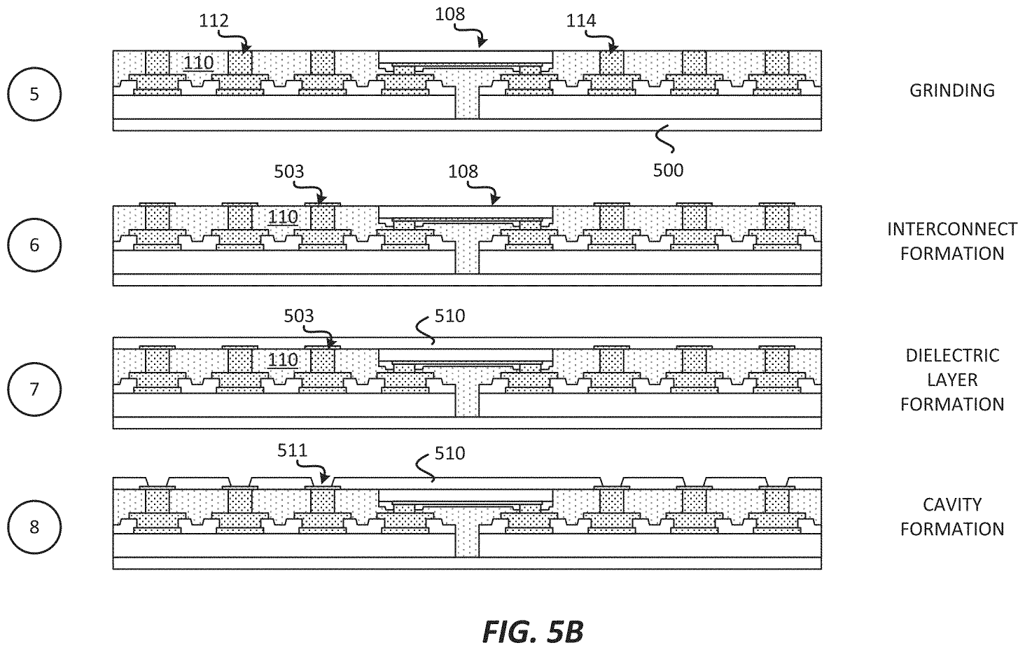

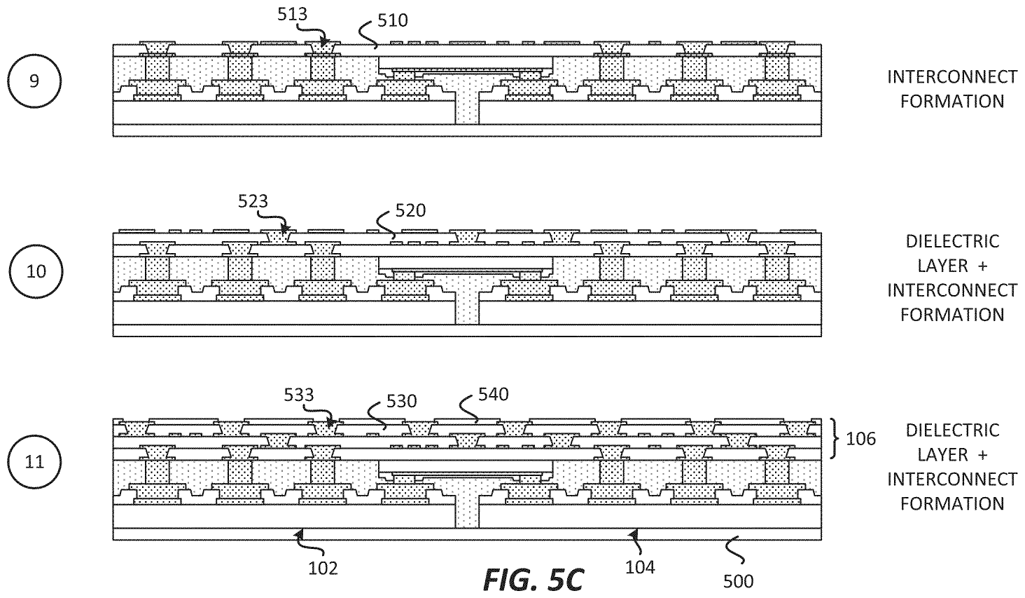

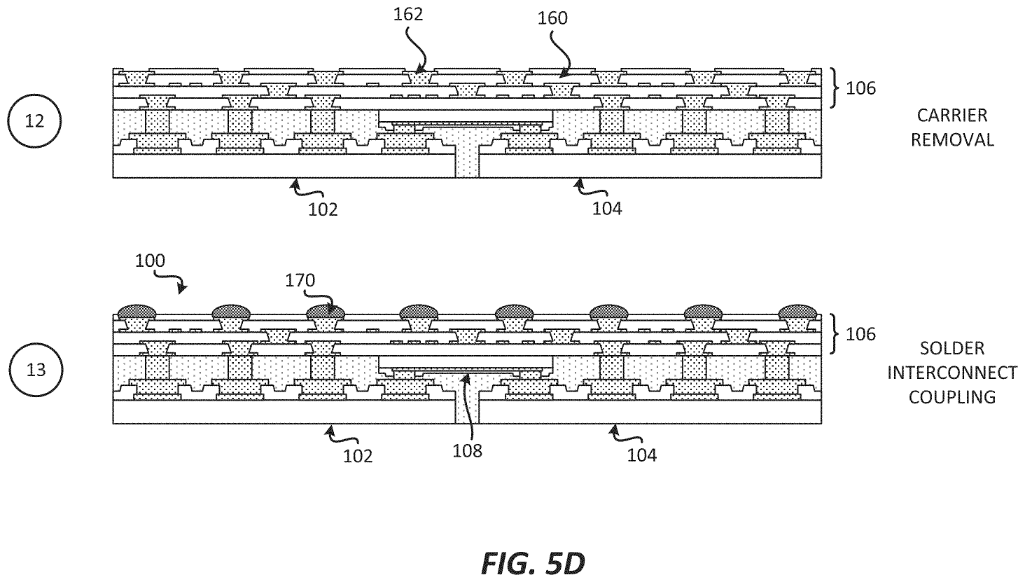

In some implementations, fabricating a package includes several processes. FIGS. 5A-5D illustrate an exemplary sequence for providing or fabricating a package. In some implementations, the sequence of FIGS. 5A-5D may be used to provide or fabricate the package 100 of FIG. 1 and/or other packages described in the present disclosure.

It should be noted that the sequence of FIGS. 5A-5D may combine one or more stages in order to simplify and/or clarify the sequence for providing or fabricating a package. In some implementations, the order of the processes may be changed or modified. In some implementations, one or more of processes may be replaced or substituted without departing from the spirit of the disclosure.

Stage 1, as shown in FIG. 5A, illustrates a state after an integrated device 102 (e.g., first integrated device) and an integrated device 104 (e.g., second integrated device) are coupled to a carrier 500. The integrated device (e.g., 102, 104) may include the die substrate (e.g., 120, 140), the plurality of pads (e.g., 124, 144) and the passivation layer (e.g., 122, 142). The integrated device (e.g., 102, 104) may also include a plurality of under bump metallization interconnects (e.g., 126, 146). The integrated device (e.g., 102, 104) may include a die (e.g., bare die, first die). In some implementations, a front end of line (FEOL) process may be used to fabricate the integrated device or part of the integrated device.

Stage 2 illustrates a state after a bridge 108 is coupled to the integrated device 102 and the integrated device 104. The bridge 108 may be coupled to the integrated device 102 and the integrated device 104 such that a front side of the bridge 108 faces a front side of the integrated device 102 and a front side of the integrated device 104. In some implementations, a metal-to-metal oxide bonding process and/or a hybrid bonding process may be used to couple the bridge 108 to the integrated devices 102 and 104. The result may be a bridge 108 that is coupled to the integrated devices 102 and 104 in a similar manner as described for the package 100 in FIG. 1. In some implementations, the bridge 108 may be coupled to the integrated device 102 and the integrated device 104 through a plurality of solder interconnects by way of a solder reflow process. The result may be a bridge 108 that is coupled to the integrated devices 102 and 104 in a similar manner as described for the package 200 in FIG. 2.

Stage 3 illustrates a state after the plurality of pillar interconnects 112 is formed over the integrated device 102. The plurality of pillar interconnects 112 (e.g., first plurality of pillar interconnects) may be considered part of the integrated device 102. The plurality of pillar interconnects 112 may be formed over the plurality of pads 124. A plating process may be used to form the plurality of pillar interconnects 112. Stage 2 also illustrates a state after the plurality of pillar interconnects 114 is formed over the integrated device 104. The plurality of pillar interconnects 114 (e.g., second plurality of pillar interconnects) may be considered part of the integrated device 104. The plurality of pillar interconnects 114 may be formed over the plurality of pads 144. A plating process may be used to form the plurality of pillar interconnects 114.

Stage 4 illustrates a state after an encapsulation layer 110 is formed over the carrier 500, the integrated device 102, the integrated device 104, the bridge 108, the plurality of pillar interconnects 112 and the plurality of pillar interconnects 114. The encapsulation layer 110 may include a mold, a resin, an epoxy and/or polymer. The encapsulation layer 110 may be a means for encapsulation. The process of forming and/or disposing the encapsulation layer 110 may include using a compression and transfer molding process, a sheet molding process, or a liquid molding process.

Stage 5, as shown in FIG. 5B, illustrates a state after portions of the encapsulation layer 110, portions of the bridge 108, portions of the plurality of pillar interconnects 112, and/or portions of the plurality of pillar interconnects 114 are removed. A grinding process and/or polishing process may be used to removed portions of the encapsulation layer 110, portions of the bridge 108, portions of the plurality of pillar interconnects 112, and/or portions of the plurality of pillar interconnects 114. After the grinding process and/or polishing process, a surface (e.g., top surface) of the encapsulation layer 110 may be planar with a surface (e.g., top surface) of the plurality of pillar interconnects 112, a surface of the plurality of pillar interconnects 114 and/or a surface of the back side of the bridge 108. The grinding and/or polishing process may help reduce the overall thickness of the package.

Stage 6 illustrates a state after a plurality of metallization interconnects 503 is formed over the plurality of pillar interconnects 112, the plurality of pillar interconnects 114 and the encapsulation layer 110. The metallization interconnect 503 may include a plurality of redistribution layer interconnects. The plurality of metallization interconnects 503 may include redistribution layer interconnects that include U-shape interconnects or V-shape interconnects. A deposition process (e.g., plating process) may be used to form the plurality of metallization interconnects 503. Forming the metallization interconnects 503 may include forming a seed layer, performing a lithography process, a plating process, a stripping process and/or an etching process.

Stage 7 illustrates a state after a dielectric layer 510 is formed over the metallization interconnects 503. A deposition process may be used to form the dielectric layer 510.

Stage 8 illustrates a state after opening(s) 511 is formed in the dielectric layer 510. An etching process may be used to form the opening(s) 511.

Stage 9, as shown in FIG. 5C, illustrates a state after a plurality of metallization interconnects 513 is formed in and over the dielectric layer 510. Some of the plurality of metallization interconnects 513 may be formed in the cavity (e.g., 511) of the dielectric layer 510. The plurality of metallization interconnects 513 may be coupled to the plurality of metallization interconnects 503. Forming the plurality of metallization interconnects 513 may include forming a seed layer, performing a lithography process, a plating process, a stripping process and/or an etching process.

Stage 10 illustrates a state after a dielectric layer 520 and a plurality of metallization interconnects 523 are formed over the dielectric layer 510 and the plurality of metallization interconnects 513. The plurality of metallization interconnects 523 may be coupled to the plurality of metallization interconnects 513. A deposition process may be used to form the dielectric layer 520. Forming the plurality of metallization interconnects 523 may include forming a seed layer, performing a lithography process, a plating process, a stripping process and/or an etching process.

Stage 11 illustrates a state after a dielectric layer 530, a plurality of metallization interconnects 533, and a dielectric layer 540 are formed over the dielectric layer 520 and the plurality of metallization interconnects 523. The plurality of metallization interconnects 533 may be coupled to the plurality of metallization interconnects 523. A deposition process may be used to form the dielectric layer 530. Forming the plurality of metallization interconnects 533 may include forming a seed layer, performing a lithography process, a plating process, a stripping process and/or an etching process. A deposition process and an etching process may be used to form the dielectric layer 540. Stage 11 may illustrate the metallization portion 106 that includes at least one dielectric layer 160 and a plurality of metallization interconnects 162. The at least one dielectric layer 160 may represent the dielectric layer 510, the dielectric layer 520, the dielectric layer 530 and/or the dielectric layer 540. The plurality of metallization interconnects 162 may represent the plurality of metallization interconnects 503, 513, 523 and/or 533.

Stage 12, as shown in FIG. 5D, illustrates a state after the carrier 500 has been removed. Removing the carrier 500 may include decoupling the carrier 500 from the back side of the integrated device 102 and the back side of the integrated device 104. The carrier 500 may be removed, grinded off and/or peeled off from the integrated device 102, the integrated device 104 and the encapsulation layer 110.

Stage 13 illustrates after the plurality of solder interconnects 170 is coupled to the plurality of metallization interconnects 162. Stage 13 may illustrate a package 100 that includes the integrated device 102, the integrated device 104, the bridge 108, the encapsulation layer 110 and the metallization portion 106.

### Exemplary Flow Diagram of a Method for Fabricating a Package Comprising Integrated Devices Coupled Through a Bridge

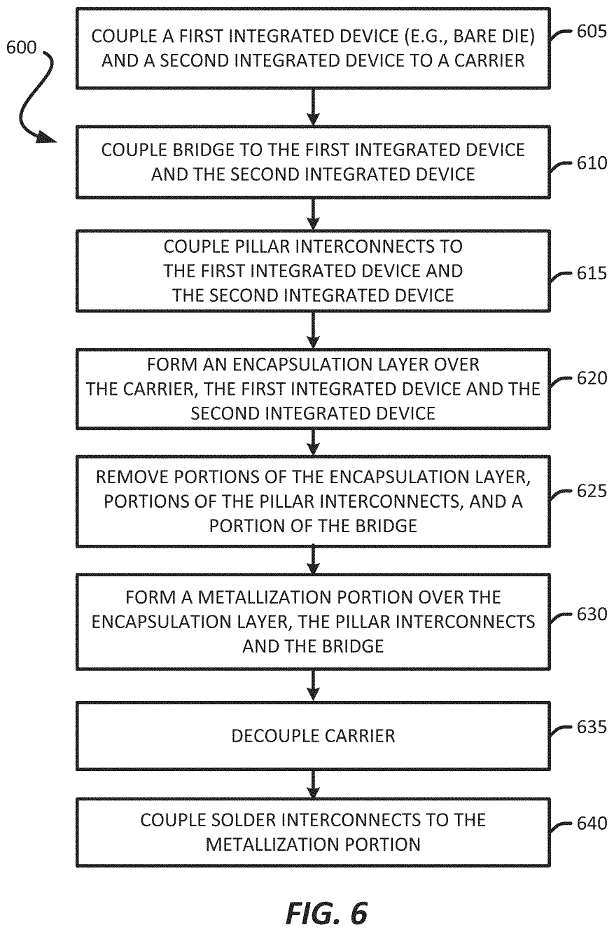

In some implementations, fabricating a package includes several processes. FIG. 6 illustrates an exemplary flow diagram of a method 600 for providing or fabricating a package. In some implementations, the method 600 of FIG. 6 may be used to provide or fabricate the packages of FIGS. 1-2 and/or other packages described in the present disclosure.

It should be noted that the method 600 of FIG. 6 may combine one or more processes in order to simplify and/or clarify the method for providing or fabricating a package. In some implementations, the order of the processes may be changed or modified.

The method couples (at 605) an integrated device 102 (e.g., first integrated device) and an integrated device 104 (e.g., second integrated device) to a carrier (e.g., 500). The integrated device (e.g., 102, 104) may include the die substrate (e.g., 120, 140), the plurality of pads (e.g., 124, 144) and the passivation layer (e.g., 122, 142). The integrated device (e.g., 102, 104) may also include a plurality of under bump metallization interconnects (e.g., 126, 146). The integrated device (e.g., 102, 104) may include a die (e.g., bare die, first die). In some implementations, a front end of line (FEOL) process may be used to fabricate the integrated device or part of the integrated device. Stage 1 of FIG. 5A, illustrates and describes an example of coupling integrated devices to a carrier.

The method couples (at 610) a bridge (e.g., 108) to the integrated devices (e.g., 102, 104). The bridge 108 may be coupled to the integrated device 102 and the integrated device 104 such that a front side of the bridge 108 faces a front side of the integrated device 102 and a front side of the integrated device 104. In some implementations, a metal-to-metal oxide bonding process and/or a hybrid bonding process may be used to couple the bridge 108 to the integrated devices 102 and 104. The result may be a bridge 108 that is coupled to the integrated devices 102 and 104 in a similar manner as described for the package 100 in FIG. 1. In some implementations, the bridge 108 may be coupled to the integrated device 102 and the integrated device 104 through a plurality of solder interconnects by way of a solder reflow process. The result may be a bridge 108 that is coupled to the integrated devices 102 and 104 in a similar manner as described for the package 200 in FIG. 2. Stage 2 of FIG. 5A, illustrates and describes an example of a bridge coupled to integrated devices.

The method couples (at 615) a plurality of pillar interconnects (e.g., 112, 114) to the integrated devices (e.g., 102, 104). For example, the method may form a plurality of pillar interconnects 112 over the plurality of under bump metallization interconnects 126 of the integrated device 102, and a plurality of pillar interconnects 114 over the plurality of under bump metallization interconnects 146 of the integrated device 104. A plating process may be used to form the plurality of pillar interconnects 112 and 114. Stage 3 of FIG. 5A, illustrates and describes an example of forming pillar interconnects over integrated devices.

The method forms (at 620) an encapsulation layer 110 over the carrier 500, the integrated device 102, the integrated device 104, the bridge 108, the plurality of pillar interconnects 112 and the plurality of pillar interconnects 114. The encapsulation layer 110 may include a mold, a resin, an epoxy and/or polymer. The encapsulation layer 110 may be a means for encapsulation. The process of forming and/or disposing the encapsulation layer 110 may include using a compression and transfer molding process, a sheet molding process, or a liquid molding process. Stage 4 of FIG. 5A illustrates and describes an example of forming an encapsulation layer.

The method removes (at 625) portions of the encapsulation layer 110, portions of the bridge 108, portions of the plurality of pillar interconnects 112 and/or portions of the plurality of pillar interconnects 114. A grinding process and/or polishing process may be used to removed portions of the encapsulation layer 110, portions of the bridge 108, portions of the plurality of pillar interconnects 112, and/or portions of the plurality of pillar interconnects 114. After the grinding process and/or polishing process, a surface (e.g., top surface) of the encapsulation layer 110 may be planar with a surface (e.g., top surface) of the plurality of pillar interconnects 112, a surface of the plurality of pillar interconnects 114 and/or a surface of the back side of the bridge 108. Stage 5 of FIG. 5B, illustrates and describes an example of removing portions of an encapsulation layer, portions of a bridge, and portions of a plurality of pillar interconnects.

The method forms (at 630) a metallization portion (e.g., 106). The metallization portion 106 may be a first metallization portion. Forming the metallization portion 106 may include forming at least one dielectric layer (e.g., 160) and forming a plurality of metallization interconnects (e.g., 162). Forming at least one dielectric layer may include a deposition process. Forming a plurality of metallization interconnects may include forming a seed layer, performing a lithography process, a plating process, a stripping process and/or an etching process. In some implementations, forming the metallization portion may include iteratively forming a plurality of metallization interconnects and forming a dielectric layer. Stage 6 of FIG. 5B through Stage 11 of FIG. 5C, illustrate and describe an example of forming a metallization portion.

The method decouples (at 635) the carrier (e.g., 500) from a back side of an integrated device. Decoupling the carrier 500 may include removing the carrier 500 from the back side of the integrated device 102 and the back side of the integrated device 104. The carrier 500 may be removed, grinded off and/or peeled off from the integrated device 102, the integrated device 104 and the encapsulation layer 110. Stage 12 of FIG. 5D, illustrates and describes an example of a carrier that has been decoupled.

The method couples (at 640) a plurality of solder interconnects (e.g., 170) to the metallization portion (e.g., 106). A solder reflow process may be used to couple the plurality of solder interconnects 170 to a plurality of metallization interconnects 162. Stage 13 of FIG. 5D, illustrates and describes an example of coupling a plurality of solder interconnects to a plurality of metallization interconnects of a metallization portion of a package.

### Exemplary Sequence for Fabricating a Package Comprising Integrated Devices Coupled Through a Bridge

In some implementations, fabricating a package includes several processes. FIGS. 7A-7C illustrate an exemplary sequence for providing or fabricating a package. In some implementations, the sequence of FIGS. 7A-7C may be used to provide or fabricate the package 300 of FIG. 3 and/or other packages described in the present disclosure.

It should be noted that the sequence of FIGS. 7A-7C may combine one or more stages in order to simplify and/or clarify the sequence for providing or fabricating a package. In some implementations, the order of the processes may be changed or modified. In some implementations, one or more of processes may be replaced or substituted without departing from the spirit of the disclosure.

Stage 1, as shown in FIG. 7A, illustrates a metallization portion 306 that is formed over a carrier 700. The metallization portion 306 includes at least one dielectric layer 360 and a plurality of metallization interconnects 362. The metallization portion 306 may be a second metallization portion. A deposition process may be used to form the at least one dielectric layer 360. Forming the plurality of metallization interconnects 362 may include forming a seed layer, performing a lithography process, a plating process, a stripping process and/or an etching process. A process similar to the process of Stage 6 FIG. 5B through Stage 11 of FIG. 5C, may be used to form the metallization portion 306.

Stage 2 illustrates a state after the integrated device 102 (e.g., first integrated device) and the integrated device 104 (e.g., second integrated device) are coupled to a metallization portion 306. In some implementations, an adhesive (e.g., 702, 704) may be used to couple the integrated devices to the metallization portion 306. For example, (i) an adhesive 702 may be coupled to the back side of the integrated device 102 and the metallization portion 306, and (ii) an adhesive 704 may be coupled to the back side of the integrated device 104 and the metallization portion 306. The integrated device (e.g., 102, 104) may include the die substrate (e.g., 120, 140), the plurality of pads (e.g., 124, 144), the plurality of under bump metallization interconnects (e.g., 126, 146) and the passivation layer (e.g., 122, 142). The integrated device (e.g., 102, 104) may include a die (e.g., bare die, first die). In some implementations, a front end of line (FEOL) process may be used to fabricate the integrated device or part of the integrated device.

Stage 3 illustrates a state after the plurality of pillar interconnects 112 is formed over the integrated device 102. The plurality of pillar interconnects 112 (e.g., first plurality of pillar interconnects) may be considered part of the integrated device 102. The plurality of pillar interconnects 112 may be formed over the plurality of under bump metallization interconnects 126. A plating process may be used to form the plurality of pillar interconnects 112. Stage 3 also illustrates a state after the plurality of pillar interconnects 114 is formed over the integrated device 104. The plurality of pillar interconnects 114 (e.g., second plurality of pillar interconnects) may be considered part of the integrated device 104. The plurality of pillar interconnects 114 may be formed over the plurality of under bump metallization interconnects 146. A plating process may be used to form the plurality of pillar interconnects 114.

Stage 4 illustrates a state after a bridge 108 is coupled to the integrated device 102 and the integrated device 104. The bridge 108 may be coupled to the integrated device 102 and the integrated device 104 such that a front side of the bridge 108 faces a front side of the integrated device 102 and a front side of the integrated device 104. In some implementations, a metal-to-metal oxide bonding process and/or a hybrid bonding process may be used to couple the bridge 108 to the integrated devices 102 and 104. The result may be a bridge 108 that is coupled to the integrated devices 102 and 104 in a similar manner as described for the package 100 in FIG. 1. In some implementations, the bridge 108 may be coupled to the integrated device 102 and the integrated device 104 through a plurality of solder interconnects by way of a solder reflow process. The result may be a bridge 108 that is coupled to the integrated devices 102 and 104 in a similar manner as described for the package 200 in FIG. 2.

Stage 5, as shown in FIG. 7B, illustrates a state after an encapsulation layer 110 is formed over the metallization portion 306, the integrated device 102, the integrated device 104, the bridge 108, the plurality of pillar interconnects 112 and the plurality of pillar interconnects 114. The encapsulation layer 110 may include a mold, a resin, an epoxy and/or polymer. The encapsulation layer 110 may be a means for encapsulation. The process of forming and/or disposing the encapsulation layer 110 may include using a compression and transfer molding process, a sheet molding process, or a liquid molding process.

Stage 6 illustrates a state after portions of the encapsulation layer 110, portions of the bridge 108, portions of the plurality of pillar interconnects 112, and/or portions of the plurality of pillar interconnects 114 are removed. A grinding process and/or polishing process may be used to removed portions of the encapsulation layer 110, portions of the bridge 108, portions of the plurality of pillar interconnects 112, and/or portions of the plurality of pillar interconnects 114. After the grinding process and/or polishing process, a surface (e.g., top surface) of the encapsulation layer 110 may be planar with a surface (e.g., top surface) of the plurality of pillar interconnects 112, a surface of the plurality of pillar interconnects 114 and/or a surface of the back side of the bridge 108.

Stage 7 illustrates a state after a plurality of cavities 710 is formed in the encapsulation layer 110. A laser process (e.g., laser ablation) may be used to form the cavities 710 in the encapsulation layer 110. The plurality of cavities 710 may expose portions of the plurality of metallization interconnects 362.

Stage 8 illustrates a state after a plurality of pillar interconnects 312 is formed in the cavities 710 of the encapsulation layer 110. A plating process may be used to form the plurality of pillar interconnects 312. The plurality of pillar interconnects 312 may be coupled to the plurality of metallization interconnects 362.

Stage 9, as shown in FIG. 7C, illustrates a metallization portion 106 that is formed over the encapsulation layer 110, the plurality of pillar interconnects 312, the plurality of pillar interconnects 112, the plurality of pillar interconnects 114 and a back side of the bridge 108. The metallization portion 106 includes at least one dielectric layer 160 and a plurality of metallization interconnects 162. A deposition process may be used to form the at least one dielectric layer 160. Forming the plurality of metallization interconnects 162 may include forming a seed layer, performing a lithography process, a plating process, a stripping process and/or an etching process. A process similar to the process of Stage 6 FIG. 5B through Stage 11 of FIG. 5C, may be used to form the metallization portion 106.

Stage 10 illustrates a state after the carrier 700 has been removed. Removing the carrier 700 may include decoupling the carrier 700 from the metallization portion 306. The carrier 700 may be removed, grinded off and/or peeled off from the metallization portion 306.

Stage 11 illustrates after the plurality of solder interconnects 170 is coupled to the plurality of metallization interconnects 162 of the metallization portion 106. Stage 13 may illustrate a package 300 that includes the integrated device 102, the integrated device 104, the bridge 108, the encapsulation layer 110, the metallization portion 106 (e.g., first metallization portion) and the metallization portion 306 (e.g., second metallization portion). Stage 11 may illustrate the package 300. In some implementations, the integrated device 302 and/or the integrated device 304 may be coupled to the metallization portion 306 of the package 300 to form a package on package (PoP).

### Exemplary Flow Diagram of a Method for Fabricating a Package Comprising Integrated Devices Coupled Through a Bridge

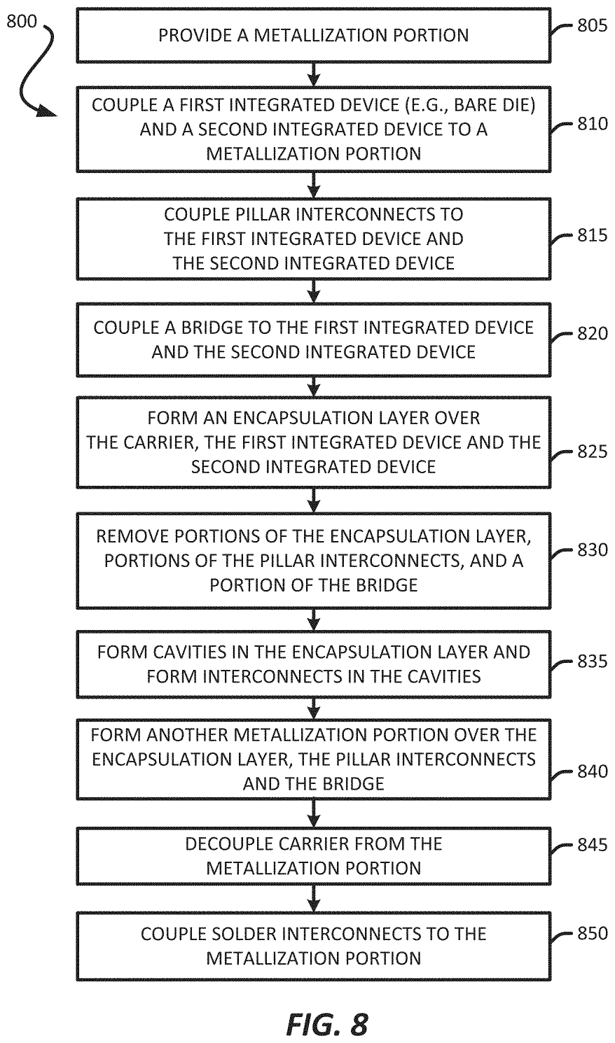

In some implementations, fabricating a package includes several processes. FIG. 8 illustrates an exemplary flow diagram of a method 800 for providing or fabricating a package. In some implementations, the method 800 of FIG. 8 may be used to provide or fabricate the package 300 of FIG. 3 and/or other packages described in the present disclosure.

It should be noted that the method 800 of FIG. 8 may combine one or more processes in order to simplify and/or clarify the method for providing or fabricating a package. In some implementations, the order of the processes may be changed or modified.

The method forms (at 805) a metallization portion (e.g., 306) over a carrier (e.g., 700). The metallization portion 306 may be a second metallization portion. Forming the metallization portion 306 may include forming at least one dielectric layer (e.g., 360) and forming a plurality of metallization interconnects (e.g., 362). Forming at least one dielectric layer may include a deposition process. Forming the plurality of metallization interconnects may include forming a seed layer, performing a lithography process, a plating process, a stripping process and/or an etching process. In some implementations, forming the metallization portion may include iteratively forming a plurality of metallization interconnects and forming a dielectric layer. Stage 1 of FIG. 7A illustrates and describes an example of forming a metallization portion.

The method couples (at 810) an integrated device 102 (e.g., first integrated device) and an integrated device 104 (e.g., second integrated device) to the metallization portion (e.g., 306). An adhesive (e.g., 702, 704) may be used to couple a back side of the integrated device 102 and a back side of the integrated device 104 to the metallization portion 306. The integrated device (e.g., 102, 104) may include the die substrate (e.g., 120, 140), the plurality of pads (e.g., 124, 144), the plurality of under bump metallization interconnects (e.g., 126, 146) and the passivation layer (e.g., 122, 142). The integrated device (e.g., 102, 104) may include a die (e.g., bare die, first die). In some implementations, a front end of line (FEOL) process may be used to fabricate the integrated device or part of the integrated device. Stage 2 of FIG. 7A, illustrates and describes an example of coupling integrated devices to a metallization portion.

The method couples (at 815) pillar interconnects (e.g., 112, 114) to the integrated devices (e.g., 102, 104). For example, the method may form a plurality of pillar interconnects 112 over the plurality of under bump metallization interconnects 126 of the integrated device 102, and a plurality of pillar interconnects 114 over the plurality of under bump metallization interconnects 146 of the integrated device 104. A plating process may be used to form the plurality of pillar interconnects 112 and 114. Stage 3 of FIG. 7A, illustrates and describes an example of forming pillar interconnects over integrated devices.

The method couples (at 820) a bridge (e.g., 108) to the integrated devices (e.g., 102, 104). The bridge 108 may be coupled to the integrated device 102 and the integrated device 104 such that a front side of the bridge 108 faces a front side of the integrated device 102 and a front side of the integrated device 104. In some implementations, a metal-to-metal oxide bonding process and/or a hybrid bonding process may be used to couple the bridge 108 to the integrated devices 102 and 104. The result may be a bridge 108 that is coupled to the integrated devices 102 and 104 in a similar manner as described for the package 100 in FIG. 1. In some implementations, the bridge 108 may be coupled to the integrated device 102 and the integrated device 104 through a plurality of solder interconnects by way of a solder reflow process. The result may be a bridge 108 that is coupled to the integrated devices 102 and 104 in a similar manner as described for the package 200 in FIG. 2. Stage 4 of FIG. 7A, illustrates and describes an example of a bridge coupled to integrated devices.

The method forms (at 825) an encapsulation layer 110 over the metallization portion 306, the integrated device 102, the integrated device 104, the bridge 108, the plurality of pillar interconnects 112 and the plurality of pillar interconnects 114. The encapsulation layer 110 may include a mold, a resin, an epoxy and/or polymer. The encapsulation layer 110 may be a means for encapsulation. The process of forming and/or disposing the encapsulation layer 110 may include using a compression and transfer molding process, a sheet molding process, or a liquid molding process. Stage 5 of FIG. 7B illustrates and describes an example of forming an encapsulation layer.

The method removes (at 830) portions of the encapsulation layer 110, portions of the bridge 108, portions of the plurality of pillar interconnects 112 and/or portions of the plurality of pillar interconnects 114. A grinding process and/or polishing process may be used to removed portions of the encapsulation layer 110, portions of the bridge 108, portions of the plurality of pillar interconnects 112, and/or portions of the plurality of pillar interconnects 114. After the grinding process and/or polishing process, a surface (e.g., top surface) of the encapsulation layer 110 may be planar with a surface (e.g., top surface) of the plurality of pillar interconnects 112, a surface of the plurality of pillar interconnects 114 and/or a surface of the back side of the bridge 108. Stage 6 of FIG. 7B, illustrates and describes an example of removing portions of an encapsulation layer, portions of a bridge, and portions of a plurality of pillar interconnects.

The method forms (at 835) a plurality of pillar interconnects (e.g., 312) in the encapsulation layer 110. Forming (at 835) the plurality of pillar interconnects 312 may include forming cavities (e.g., 710) in the encapsulation layer 110 and forming the plurality of pillar interconnects 312 in the cavities 710 of the encapsulation layer 110. A laser process (e.g., laser ablation) may be used to form the cavities 710. A plating process may be used to form the plurality of pillar interconnects 312 in the cavities 710 of the encapsulation layer 110. Stages 7-8 of FIG. 7B, illustrate and describe an example of forming cavities and interconnects in an encapsulation layer.

The method forms (at 840) a metallization portion (e.g., 106). The metallization portion 106 may be a first metallization portion. Forming the metallization portion 106 may include forming at least one dielectric layer (e.g., 160) and forming a plurality of metallization interconnects (e.g., 162). Forming at least one dielectric layer may include a deposition process. Forming the plurality of metallization interconnects may include forming a seed layer, performing a lithography process, a plating process, a stripping process and/or an etching process. In some implementations, forming the metallization portion may include iteratively forming a plurality of metallization interconnects and forming a dielectric layer. Stage 9 of FIG. 7C illustrates and describes an example of forming a metallization portion.

The method decouples (at 845) the carrier (e.g., 700) from the metallization portion 306. Decoupling the carrier 700 may include removing the carrier 700 from the metallization portion 306. The carrier 700 may be removed, grinded off and/or peeled off from the metallization portion 306. Stage 10 of FIG. 7C, illustrates and describes an example of a of a package after a carrier has been decoupled.

The method couples (at 850) a plurality of solder interconnects (e.g., 170) to the metallization portion (e.g., 106). A solder reflow process may be used to couple the plurality of solder interconnects 170 to a plurality of metallization interconnects 162. Stage 11 of FIG. 7C, illustrates and describes an example of a plurality of solder interconnects coupled to a plurality of metallization interconnects of a metallization portion.

### Exemplary Electronic Devices

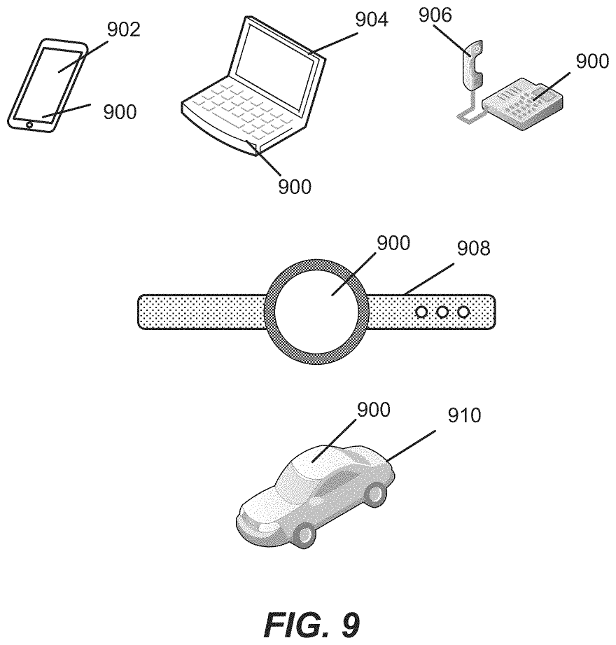

FIG. 9 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 902, a laptop computer device 904, a fixed location terminal device 1006, a wearable device 908, or automotive vehicle 910 may include a device 900 as described herein. The device 900 may be, for example, any of the devices and/or integrated circuit (IC) packages described herein. The devices 902, 904, 906 and 908 and the vehicle 910 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-4, 5A-5D, 6, 7A-7C, and 8-9 may be rearranged and/or combined into a single component, process, feature or function or embodied in several components, processes, or functions. Additional elements, components, processes, and/or functions may also be added without departing from the disclosure. It should also be noted FIGS. 1-4, 5A-5D, 6, 7A-7C, and 8-9 and its corresponding description in the present disclosure is not limited to dies and/or ICs. In some implementations, FIGS. 1-4, 5A-5D, 6, 7A-7C, and 8-9 and its corresponding description may be used to manufacture, create, provide, and/or produce devices and/or integrated devices. In some implementations, a device may include a die (e.g., logic die), an integrated device, an integrated passive device (IPD) (e.g., passive die), a die package, an integrated circuit (IC) device, a device package, an integrated circuit (IC) package, a wafer, a semiconductor device, a package-on-package (PoP) device, and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The following provides an overview of aspects of the present disclosure:

Aspect 1: A package comprising: a first integrated device comprising a first plurality of under bump metallization interconnects; a second integrated device comprising a second plurality of under bump metallization interconnects; a bridge coupled to the first integrated device and the second integrated device; an encapsulation layer at least partially encapsulating the first integrated device, the second integrated device, and the bridge; a metallization portion located over the first integrated device, the second integrated device, the bridge and the encapsulation layer, wherein the metallization portion includes at least one dielectric layer and a plurality of metallization interconnects; a first plurality of pillar interconnects coupled to the first plurality of under bump metallization interconnects and the metallization portion, the first plurality of pillar interconnects located in the encapsulation layer; and a second plurality of pillar interconnects coupled to the second plurality of under bump metallization interconnects and the metallization portion, the second plurality of pillar interconnects located in the encapsulation layer.

Aspect 2: The package of aspect 1, wherein the bridge comprises a plurality of bridge interconnects coupled to the first integrated device and the second integrated device.

Aspect 3: The package of aspect 2, wherein the plurality of bridge interconnects is coupled to at least one under bump metallization interconnect from the first integrated device and at least one under bump metallization interconnect from the second integrated device.

Aspect 4: The package of aspects 2 through 3, wherein the plurality of bridge interconnects comprises a plurality of bridge under bump metallization interconnects.

Aspect 5: The package of aspect 4, wherein the plurality of bridge under bump metallization interconnects is coupled to at least one under bump metallization interconnect from the first integrated device and at least one under bump metallization interconnect from the second integrated device.

Aspect 6: The package of aspects 2 through 5, wherein the plurality of bridge interconnects is coupled to the first plurality of under bump metallization interconnects and the second plurality of under bump metallization interconnects through hybrid bonding.

Aspect 7: The package of aspects 2 through 5, wherein the plurality of bridge interconnects is coupled to the first plurality of under bump metallization interconnects and the second plurality of under bump metallization interconnects through at least one solder interconnect.

Aspect 8: The package of aspects 2 through 7, wherein the plurality of bridge interconnects comprises a minimum width of 0.5 micrometers.

Aspect 9: The package of aspects 2 through 8, wherein the plurality of bridge interconnects comprises a width in a range of about 0.5-1 micrometer.

Aspect 10: The package of aspects 1 through 9, further comprising a second metallization portion located over the back side of the first integrated device and the back side of the second integrated device, wherein the second metallization portion includes at least one second dielectric layer and a second plurality of metallization interconnects.

Aspect 11: The package of aspect of 10, further comprising a third plurality of pillar interconnects coupled to the metallization portion and the second metallization portion, wherein the third plurality of pillar interconnects is located in the encapsulation layer.

Aspect 12: An apparatus comprising: a first integrated device comprising a first plurality of under bump metallization interconnects; a second integrated device comprising a second plurality of under bump metallization interconnects; means for bridge interconnection coupled to the first integrated device and the second integrated device; means for encapsulation at least partially encapsulating the first integrated device, the second integrated device, and the means for bridge interconnection; a metallization portion located over the first integrated device, the second integrated device, the means for bridge interconnection and the means for encapsulation, wherein the metallization portion includes at least one dielectric layer and means for metallization interconnection; a first plurality of pillar interconnects coupled to the first plurality of under bump metallization interconnects and the metallization portion, the first plurality pillar of interconnects located in the means for encapsulation; and a second plurality of pillar interconnects coupled to the second plurality of under bump metallization interconnects and the metallization portion, the second plurality of pillar interconnects located in the means for encapsulation.

Aspect 13: The apparatus of aspect 12, wherein the means for bridge interconnection comprises a plurality of bridge interconnects coupled to the first integrated device and the second integrated device.

Aspect 14: The apparatus of aspect 13, wherein the plurality of bridge interconnects is coupled to at least one under bump metallization interconnect from the first integrated device and at least one under bump metallization interconnect from the second integrated device.

Aspect 15: The apparatus of aspects 13 through 14, wherein the plurality of bridge interconnects comprises a plurality of bridge under bump metallization interconnects.

Aspect 16: The apparatus of aspect 15, wherein the plurality of bridge under bump metallization interconnects is coupled to at least one under bump metallization interconnect from the first integrated device and at least one under bump metallization interconnect from the second integrated device.

Aspect 17: The apparatus of aspects 13 through 16, wherein the plurality of bridge interconnects is coupled to the first plurality of under bump metallization interconnects and the second plurality of under bump metallization interconnects through hybrid bonding.

Aspect 18: The apparatus of aspects 13 through 16, wherein the plurality of bridge interconnects is coupled to the first plurality of under bump metallization interconnects and the second plurality of under bump metallization interconnects through at least one solder interconnect.

Aspect 19: The apparatus of aspects 13 through 18, wherein the plurality of bridge interconnects comprises a minimum width of 0.5 micrometers.

Aspect 20: The apparatus of aspects 13 through 19, wherein the plurality of bridge interconnects comprises a width in a range of about 0.5-1 micrometer.

Aspect 21: The apparatus of aspects 12 through 20, further comprising a second metallization portion located over the back side of the first integrated device and the back side of the second integrated device, wherein the second metallization portion includes at least one second dielectric layer and a means for second metallization interconnection.

Aspect 22: The apparatus of aspect 21, further comprising a third plurality of pillar interconnects coupled to the metallization portion and the second metallization portion, wherein the third plurality of pillar interconnects is located in the means for encapsulation.

Aspect 23: The apparatus of aspects 12 through 22, wherein the apparatus includes a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

Aspect 24: A method for fabricating a package. The method couples a bridge coupled to a first integrated device and a second integrated device. The first integrated device comprises a first plurality of under bump metallization interconnects. The second integrated device comprises a second plurality of under bump metallization interconnects. The method forms a first plurality of interconnects over the first plurality of under bump metallization interconnects. The method forms a second plurality of interconnects over the second plurality of under bump metallization interconnects. The method forms an encapsulation layer that at least partially encapsulates the first integrated device, the second integrated device, the bridge, the first plurality of interconnects and the second plurality of interconnects. The method forms a metallization portion over the first integrated device, the second integrated device, the bridge and the encapsulation layer. Forming the metallization portion includes forming at least one dielectric layer and forming a plurality of metallization interconnects.

Aspect 25: The method of aspect 24, further comprising forming a second metallization portion comprises forming at least one second dielectric layer and forming a second plurality of metallization interconnects.

Aspect 26: The method of aspect 25, further comprising coupling a back side of the first integrated device and a back side of the second integrated device to the second metallization portion.

Aspect 27: The method of aspect 26, wherein the back side of the first integrated device and the back side of the second integrated device is coupled to the second metallization portion through an adhesive.

Aspect 28: The method of aspects 24 through 27, wherein the bridge comprises a plurality of bridge interconnects coupled to the first integrated device and the second integrated device.

Aspect 29: The method of aspect 28, wherein the plurality of bridge interconnects comprises a minimum width of 0.5 micrometers.

Aspect 30: The method of aspects 28 through 29, wherein the plurality of bridge interconnects comprises a width in a range of about 0.5-1 micrometer.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A package comprising:
a first integrated device comprising a first plurality of under bump metallization interconnects;
a second integrated device comprising a second plurality of under bump metallization interconnects;
a bridge coupled to the first integrated device and the second integrated device;
an encapsulation layer at least partially encapsulating the first integrated device, the second integrated device, and the bridge;
a metallization portion located over the first integrated device, the second integrated device, the bridge and the encapsulation layer, wherein the metallization portion includes at least one dielectric layer and a plurality of metallization interconnects;
a first plurality of pillar interconnects coupled to the first plurality of under bump metallization interconnects and the metallization portion, the first plurality of pillar interconnects located in the encapsulation layer; and
a second plurality of pillar interconnects coupled to the second plurality of under bump metallization interconnects and the metallization portion, the second plurality of pillar interconnects located in the encapsulation layer.

2. The package of claim 1, wherein the bridge comprises a plurality of bridge interconnects coupled to the first integrated device and the second integrated device.

3. The package of claim 2, wherein the plurality of bridge interconnects is coupled to at least one under bump metallization interconnect from the first integrated device and at least one under bump metallization interconnect from the second integrated device.

4. The package of claim 2, wherein the plurality of bridge interconnects comprises a plurality of bridge under bump metallization interconnects.

5. The package of claim 4, wherein the plurality of bridge under bump metallization interconnects is coupled to at least one under bump metallization interconnect from the first integrated device and at least one under bump metallization interconnect from the second integrated device.

6. The package of claim 2, wherein the plurality of bridge interconnects is coupled to the first plurality of under bump metallization interconnects and the second plurality of under bump metallization interconnects through hybrid bonding.

7. The package of claim 2, wherein the plurality of bridge interconnects is coupled to the first plurality of under bump metallization interconnects and the second plurality of under bump metallization interconnects through at least one solder interconnect.

8. The package of claim 2, wherein the plurality of bridge interconnects comprises a minimum width of 0.5 micrometers.

9. The package of claim 2, wherein the plurality of bridge interconnects comprises a width in a range of about 0.5-1 micrometer.

10. The package of claim 1, further comprising a second metallization portion located over the back side of the first integrated device and the back side of the second integrated device, wherein the second metallization portion includes at least one second dielectric layer and a second plurality of metallization interconnects.

11. The package of claim 10, further comprising a third plurality of pillar interconnects coupled to the metallization portion and the second metallization portion, wherein the third plurality of pillar interconnects is located in the encapsulation layer.

12. An apparatus comprising:
a first integrated device comprising a first plurality of under bump metallization interconnects;
a second integrated device comprising a second plurality of under bump metallization interconnects;
means for bridge interconnection coupled to the first integrated device and the second integrated device;
means for encapsulation at least partially encapsulating the first integrated device, the second integrated device, and the means for bridge interconnection;
a metallization portion located over the first integrated device, the second integrated device, the means for bridge interconnection and the means for encapsulation, wherein the metallization portion includes at least one dielectric layer and a means for metallization interconnection;
a first plurality of pillar interconnects coupled to the first plurality of under bump metallization interconnects and the metallization portion, the first plurality pillar of interconnects located in the means for encapsulation; and
a second plurality of pillar interconnects coupled to the second plurality of under bump metallization interconnects and the metallization portion, the second plurality of pillar interconnects located in the means for encapsulation.

13. The apparatus of claim 12, wherein the means for bridge interconnection comprises a plurality of bridge interconnects coupled to the first integrated device and the second integrated device.

14. The apparatus of claim 13, wherein the plurality of bridge interconnects is coupled to at least one under bump metallization interconnect from the first integrated device and at least one under bump metallization interconnect from the second integrated device.

15. The apparatus of claim 13, wherein the plurality of bridge interconnects comprises a plurality of bridge under bump metallization interconnects.

16. The apparatus of claim 15, wherein the plurality of bridge under bump metallization interconnects is coupled to at least one under bump metallization interconnect from the first integrated device and at least one under bump metallization interconnect from the second integrated device.

17. The apparatus of claim 13, wherein the plurality of bridge interconnects is coupled to the first plurality of under bump metallization interconnects and the second plurality of under bump metallization interconnects through hybrid bonding.

18. The apparatus of claim 13, wherein the plurality of bridge interconnects is coupled to the first plurality of under bump metallization interconnects and the second plurality of under bump metallization interconnects through at least one solder interconnect.

19. The apparatus of claim 13, wherein the plurality of bridge interconnects comprises a minimum width of 0.5 micrometers.

20. The apparatus of claim 13, wherein the plurality of bridge interconnects comprises a width in a range of about 0.5-1 micrometer.

21. The apparatus of claim 12, further comprising a second metallization portion located over the back side of the first integrated device and the back side of the second integrated device, wherein the second metallization portion includes at least one second dielectric layer and means for second metallization interconnection.

22. The apparatus of claim 21, further comprising a third plurality of pillar interconnects coupled to the metallization portion and the second metallization portion, wherein the third plurality of pillar interconnects is located in the means for encapsulation.

23. The apparatus of claim 12, wherein the apparatus includes a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

24. A method for fabricating a package, comprising:
coupling a bridge coupled to a first integrated device and a second integrated device,
wherein the first integrated device comprises a first plurality of under bump metallization interconnects, and
wherein the second integrated device comprises a second plurality of under bump metallization interconnects;
forming a first plurality of interconnects over the first plurality of under bump metallization interconnects;
forming a second plurality of interconnects over the second plurality of under bump metallization interconnects;
forming an encapsulation layer that at least partially encapsulates the first integrated device, the second integrated device, the bridge, the first plurality of interconnects and the second plurality of interconnects; and
forming a metallization portion over the first integrated device, the second integrated device, the bridge and the encapsulation layer, wherein forming the metallization portion includes forming at least one dielectric layer and forming a plurality of metallization interconnects.

25. The method of claim 24, further comprising forming a second metallization portion comprises forming at least one second dielectric layer and forming a second plurality of metallization interconnects.

26. The method of claim 25, further comprising coupling a back side of the first integrated device and a back side of the second integrated device to the second metallization portion.

27. The method of claim 26, wherein the back side of the first integrated device and the back side of the second integrated device is coupled to the second metallization portion through an adhesive.

28. The method of claim 24, wherein the bridge comprises a plurality of bridge interconnects coupled to the first integrated device and the second integrated device.

29. The method of claim 28, wherein the plurality of bridge interconnects comprises a minimum width of 0.5 micrometers.

30. The method of claim 28, wherein the plurality of bridge interconnects comprises a width in a range of about 0.5-1 micrometer.
